(19) United States
(12) Patent Application Publication
(10) Pub. No.: US 2019/0387615 A1
(43) Pub. Date: Dec. 19, 2019

(54) MULTI-LAYER INTERCONNECTED ELECTRO-THERMAL SYSTEM HAVING A THERMALLY NON-EXPANSIVE SUPPORT FOR MOUNTING POSITIONALLY RELATED SENSOR COMPONENTS

(71) Applicant: MICROSOFT TECHNOLOGY LICENSING, LLC, Redmond, WA (US)

(72) Inventors: Michael NIKKHOO, Saratoga, CA (US); Brian J. TELENO, Cupertino, CA (US); Tzu-Yuan LIN, San Jose, CA (US)

(21) Appl. No.: 16/009,117

(22) Filed: Jun. 14, 2018

(51) Int. Cl. H05K 1/02; H05K 7/20; H05K 1/03; H05K 1/18; G01J 1/42

(52) U.S. Cl. CPC H05K 1/0271; H05K 7/20336; H05K 1/0278; H05K 1/0366; H05K 1/181; H05K 2201/0287; H05K 2201/068; H05K 2201/10151; H05K 2201/10121; H05K 2201/10545; H05K 2201/10575; G01J 1/4228

(57) ABSTRACT

An electro-thermal system includes a sensor support layer for indirectly mounting “positionally related” sensor components to a circuit board layer that supports electronic components without heat from these electronic components impacting a positional relationship between the sensor components. The sensor support layer may be a fiber reinforced plastic having a low coefficient of thermal expansion (CTE). Thus, heat that reaches the sensor support layer will not cause expansion that significantly affects the nominal position between the sensor components. The sensor support layer is mounted to the circuit board layer via an adhesive having an intermediate CTE that is greater than the CTE of the sensor support layer but less than the CTE of the circuit board layer. Thus, the sensor components are indirectly mounted to the circuit board layer which is free to expand and contract due to heat variations without changing the positional relationship between the sensor components.

### BACKGROUND

Modern computing devices include a variety of sensor components for tracking a real-world environment. Such sensor components are often positionally related in the sense that it is important to maintain a nominal positional relationship therebetween. As an example, a computing device may include a structured light system that utilizes a projector to project a known pattern of invisible light into the real-world environment and a sensor to detect reflections of this known pattern. The structured light system may then calculate three-dimensional (3D) scene information based on how the reflections of the known pattern are deformed from the perspective of the sensor. Even slight variations in the positional relationship between the projector and the sensor can negatively impact how accurately the calculated 3D scene information represents the real-world environment. Accordingly, positionally related sensor components are typically mounted on dedicated support structures that are designed to maintain a nominal positional relationship therebetween.

Furthermore, calculating the 3D scene information is itself computationally intensive and so results in processing units consuming large amounts of energy and producing large amounts of heat. Modern computing device designs therefore provide physical separation between the heat generating processing units and the positionally related sensor components to minimize the amount of thermal expansion this heat causes the dedicated support structures to undergo. Unfortunately, such separation leads to an undesirable increase in the overall size of modern computing devices.

It is with respect to these and other considerations that the disclosure made herein is presented.

### SUMMARY

Technologies described herein provide an electro-thermal system that includes multiple interconnected layers having a sensor support layer for mounting positionally related sensor components. Generally described, the techniques disclosed herein enable positionally related sensor components to be indirectly mounted to a circuit board layer that supports various high-power components without heat that is emitted by these high-power components impacting a positional relationship between the sensor components. As a specific but non-limiting example, a projector that emits a known pattern of invisible light and a camera that senses reflections of the invisible light may be directly mounted to a sensor support layer at a nominal distance and/or angle from one another. The sensor support layer may be a carbon fiber reinforced plastic that has a very low (e.g., less than 10 parts per million) coefficient of thermal expansion (CTE). In this way, heat that reaches the sensor support layer will not cause expansion that significantly affects the nominal position between sensor components. The sensor support layer may be mounted to the circuit board layer via an adhesive having an intermediate CTE that is greater than the CTE of the sensor support layer but less than the CTE of the circuit board layer. In this way, the sensor components are indirectly mounted to the circuit board layer which is free to expand and contract in response to heat variations—all while the positional relationship between the sensor components is nominally maintained.

In some configurations, an electro-thermal system comprising multiple interconnected layers (referred to hereinafter as “system”) includes a circuit board layer having a pattern of conductive traces for interconnecting electronic components (e.g., random access memory (RAM), central processing units (CPUs), graphics processing units (GPUs), holographic processing units (HPUs), etc.). The conductive traces may be incorporated into an insulting substrate that supports at least some of the electronic components. The circuit board layer may have a first side and a second side that has electronic components mechanically coupled thereto (e.g., a processor may be soldered to a socket portion of the conductive traces). The substrate can be fabricated from any suitable material such as, for example, ceramics, polymers, glasses, or any other material having suitable structural and insulative properties. The circuit board layer has a coefficient of thermal expansion (CTE) defining how a size of the circuit board layer changes in response to temperature fluctuations. As a specific but non-limiting example, the circuit board layer may have a CTE of 60 parts-per-million (PPM). As used herein, the term “coefficient of thermal expansion” may be used to refer to a fractional amount that a particular material changes in size per degree change in temperature at a constant pressure.

The system may further include a sensor support layer for supporting various sensor components. The sensor support layer may have a CTE that is less than that of the circuit board layer. The sensor components may include multiple individual sensor components that have nominal positional relationships with respect to one another. As a specific but non-limiting example, the sensor components may include a projector for emitting structured light and an image sensor (e.g., a complementary metal-oxide-semiconductor (CMOS) camera) for detecting reflections of the structured light which have been distorted by objects within the real-world environment. It will be appreciated that in structured light technologies, the accuracy with which calculated 3D scene information represents the actual real-world environment depends on the degree to which a positional relationship between sensor components (e.g., a projector and image sensor) can be nominally maintained. Accordingly, the sensor support layer may be constructed from a predetermined material(s) and/or in a predetermined manner so as to minimize the CTE of the sensor support layer. In this way, fluctuations in the operating temperature of the system may have little or no effect on the positional relationship between various sensor components supported thereon—and will not negatively impact an ability of the system to accurately calculate 3D scene information. As used herein, the term “sensor components” may be used to refer to any component that is used for the purpose of sensing or tracking properties of a real-world environment. Accordingly, in the context of structured light technologies, a “light” projector that emits a known pattern of invisible light may aptly be described as a sensor component.

In some embodiments, the sensor support layer may be a fiber reinforced polymer having a CTE that is low enough for the sensor support layer to be described as substantially thermally nonresponsive. As a specific but non-limiting example, the sensor support layer may be a cured epoxy resin having a plurality of carbon fibers having axial directions that generally extend between two locations at which sensor components are mounted. In such an embodiment, it is practicable to achieve a CTE between the sensor components that is substantially equal to zero. The fibers may be arranged within the polymer so that the CTE of the sensor support layer is isotropic or, alternatively, anisotropic.

The sensor support layer may have an inner side that is oriented to face the circuit board layer and an outer side onto which the sensor components are mechanically coupled at a nominal positional relationship. For example, the sensor components can include a first sensor component that is mounted to the sensor support layer and also a second sensor component that is also mounted to the sensor support layer at a nominal distance from the first sensor component and/or at a nominal orientation (e.g., angle) with respect to the first sensor component. The sensor components may be electrically connected to various conductive tracks of the circuit board layer. In this way, the sensor components may be mechanically coupled to the outer side of the sensor support layer while being electrically coupled to the circuit board layer to communicate data to and/or receive data from the “interconnected” electronic components that are coupled to the circuit board.

In some embodiments, the sensor support layer may be mechanically coupled to the circuit board layer by an adhesive layer that is disposed between first side of the circuit board layer and inner side of the sensor support layer. In this way, the sensor components may be mechanically coupled to the circuit board without the expansion and contraction of the circuit board layer (that will inevitable occur during operation as the operating temperature fluctuates) affecting the nominal positional relationship between the sensor components. Thus, the various electronic components which are included within the system (e.g., processor units coupled to the circuit board layer) can perform computationally intensive tasks that consume large amounts of energy and emit large amounts of heat without causing relative movement to occur between sensor components. An exemplary such computational task may include deploying a processing unit (e.g., CPU and/or a dedicated HPU) to process environmental data provided by the sensor components to generate 3D scene information in substantially real time. As used herein, the term “environmental data” generally refers to a data that is generated by a sensor component and that is representative of one or more characteristics of a real-world environment.

In some embodiments, the adhesive layer may include a predetermined ratio of filler materials so as to cause the adhesive layer to have an intermediate CTE that is greater than that of the sensor support layer but less than that of the circuit board layer. This may reduce the stresses resulting from thermal mismatch between the various layers of the system.

In some embodiments, the system may further include a vapor chamber to absorb and dissipate heat that is generated by electronic components mounted to the circuit board layer and/or by the sensor components. As a specific but non-limiting example, a vapor chamber may be positioned within the system in thermal contact with one or more processing units to quickly draw heat away from the processing units and also prevent the emitted heat from reaching the sensor support layer.

These and various other features will be apparent from a reading of the following Detailed Description and a review of the associated drawings. This Summary is provided to introduce a selection of concepts in a simplified form that are further described below in the Detailed Description. This Summary is not intended to identify key features or essential features of the claimed subject matter, nor is it intended that this Summary be used to limit the scope of the claimed subject matter. Furthermore, the claimed subject matter is not limited to implementations that solve any or all disadvantages noted in any part of this disclosure.

### DRAWINGS

The Detailed Description is described with reference to the accompanying figures. In the figures, the left-most digit(s) of a reference number identifies the figure in which the reference number first appears. The same reference numbers in different figures indicate similar or identical items. References made to individual items of a plurality of items can use a reference number with another number included within a parenthetical (and/or a letter without a parenthetical) to refer to each individual item. Generic references to the items may use the specific reference number without the sequence of letters.

FIG. 1A is a perspective view of an exemplary electro-thermal system comprising multiple interconnected layers that includes a circuit board layer for interconnecting electronic components and a sensor support layer for supporting positionally related sensor components.

FIG. 1B is a perspective view of the system of FIG. 1A in which the positionally related sensor components are viewable.

FIG. 2A is a side view of an exemplary stack of multiple interconnected layers in which a circuit board layer that is supporting various electronic components is adhered to a sensor support layer that is supporting two positionally related sensor components.

FIG. 2B is a side view of the exemplary stack of FIG. 2A showing an exemplary light path that is emitted by a first sensor component and is sensed by a second sensor component and from which three-dimensional scene information can be accurately calculated when a nominal distance and nominal angle is maintained between the sensor components.

FIG. 3A illustrates an exemplary electro-thermal system comprising a circuit board that includes one or more substantially rigid regions and one or more flexible regions.

FIG. 3B illustrates the exemplary electro-thermal system of FIG. 3A with the substantially rigid regions of the circuit board are in an expanded state due to a temperature fluctuation.

FIG. 4 illustrates an exemplary electro-thermal system that includes a vapor chamber disposed between a circuit board layer that is supporting one or more electronic components and a sensor support layer that is supporting one or more sensor components.

FIG. 5 illustrates an exemplary electro-thermal system that includes a vapor chamber that is disposed between two layers of a material that restricts expansion and contraction of the vapor chamber.

FIG. 6 illustrates an exemplary sensor support layer that includes a plurality of fibers that are embedded within a polymer and that extend between a first sensor component and a second sensor component that are each mounted to the sensor support layer.

### DETAILED DESCRIPTION

The following Detailed Description describes technologies that provide an electro-thermal system having multiple interconnected layers that include a sensor support layer for mounting sensor components that are designed for operation at a nominal positional relationship with respect to one another (e.g., positionally related sensor components). Generally described, the techniques disclosed herein enable positionally related sensor components to be indirectly mounted to a circuit board layer that supports various “high-power” electronic components without heat that is emitted by these “high-power” electronic components impacting a positional relationship between the positionally related sensor components. The sensor components may be mounted to a sensor support layer having a first coefficient of thermal expansion (CTE) that is relatively lower than various other CTEs of other layers. The sensor support layer may be coupled to a circuit board layer having a second CTE that is higher than the first CTE of the sensor support layer. In some embodiments, the sensor support layer may be adhered to the circuit board layer via an adhesive that has an intermediate CTE that is higher than the first CTE of the sensor support layer and less than the second CTE of the circuit board layer. In this way, the sensor components are indirectly mounted to the circuit board layer which is free to expand and contract in response to heat variations—all while the positional relationship between the sensor components is nominally maintained.

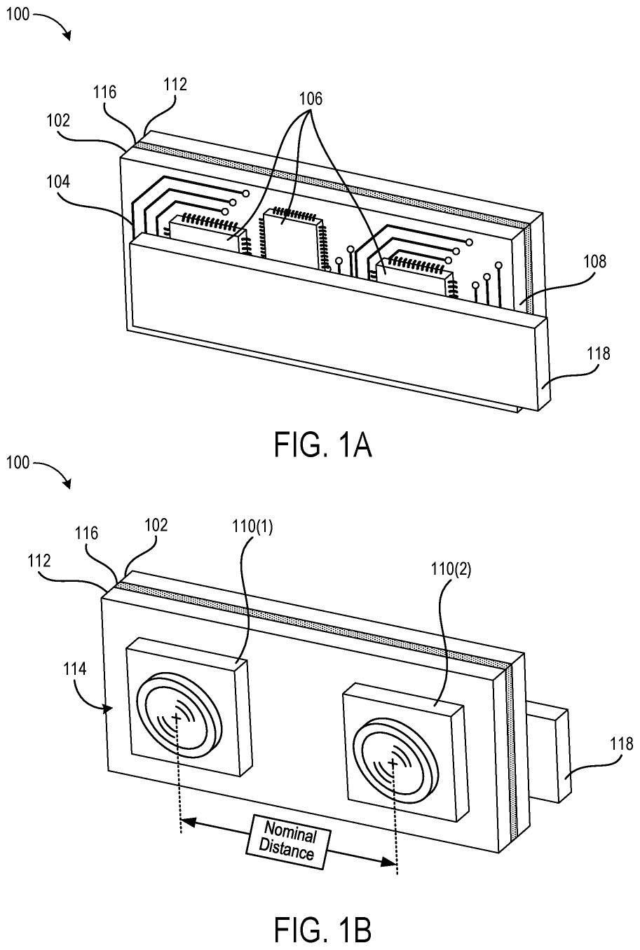

FIG. 1A is a perspective view of an exemplary electro-thermal system 100 comprising multiple interconnected layers (also referred to herein as “system”). As shown in FIG. 1A, the system 100 includes a circuit board layer 102 having a pattern of conductive traces 104 for interconnecting electronic components 106. Exemplary such electronic components 106 include, but are not limited to, random access memory (RAM), central processing units (CPUs), graphics processing units (GPUs), holographic processing units (HPUs), batteries, and so on. The conductive traces 104 are incorporated into an insulating substrate 108 that is made from a material having suitable structural properties for supporting the electronic components 106 and suitable insulative properties for electrically isolating the conductive traces 104. As described herein, the insulating substrate 108 can be rigid and/or flexible and can be fabricated from any suitable material such as, for example, polymers, ceramics, glasses, silicon, and/or any combination thereof. The conductive traces 104 can be made using any number of techniques, for example electroplating, etching, sputtering, mechanical attachment using adhesives, and/or any other suitable technique whether currently known or subsequently developed.

In the illustrated example, the circuit board layer 102 as a first side (not visible in FIG. 1A) and a second side on which the conductive traces 104 are integrated and on which the electronic components 106 are mechanically mounted. For example, the electronic components 106 may include a CPU and an HPU both of which are soldered into a socket portion of the conductive traces 104. It can be appreciated that during operation the electronic components 106 may emit heat. For example, the electronic components 106 may include an HPU that receives data from one or more sensor components 110 to continuously track physical objects within a real-world environment (e.g., in order to render holograms that realistically appear to be a part of the real-world environment). Such a task may extremely computationally intensive and, therefore, the HPU will likely consume large amounts of electrical energy and emit the consumed energy as heat.

Heat emitted by the electronic components 106 may cause temperature fluctuations within the circuit board layer 102 which, in turn, cause the circuit board layer 102 to expand and/or contract. The circuit board layer 102 may have a coefficient of thermal expansion (CTE) that is dependent upon the types of materials from which the circuit board layer 102 is constructed. It can be appreciated that the CTE of the circuit board layer 102 will define how the circuit board layer 102 changes in size in response to temperature fluctuations. As a specific but nonlimiting example, the insulating substrate 108 may be made from ceramic-based material(s) having a CTE of sixty (“60”) parts-per-million (PPM). Additionally, because heat is generated within the system 100 directly against the circuit board layer 102, temperature fluctuations may be relatively greater at the circuit board layer 102 than within other layers of the system 100. For example, in implementations where the electronic components 106 may change between states of emitting little or no heat (e.g., when computationally light tasks are being performed) to emitting large amounts of heat (e.g., when computationally intensive tasks are being performed), the temperature of the circuit board layer 102 may fluctuate by 70° Celsius or greater. Considering such a large temperature fluctuation with respect to the present example where the CTE of the circuit board layer 102 is 60 PPM, it can be appreciated that the size of the circuit board layer 102 may fluctuate 4200 PPM or greater.

Turning now to FIG. 1B, a perspective view of the system 100 of FIG. 1A is shown in which a first sensor component 110(1) and a second sensor component 110(2) are viewable. As illustrated, the sensor components 110 are mounted to a sensor support layer 112 at a nominal distance from one another. As a specific but non-limiting example, the first sensor component 110(1) and the second sensor component 110(2) may each be complementary metal oxide semiconductor (CMOS) cameras for simultaneously capturing images of a real-world environment for stereo vision (a.k.a. computer vision) purposes. Calculating accurate three-dimensional (3D) scene information using stereo vision techniques requires a precise knowledge of the distance between the cameras from which comparable images were obtained. Accordingly, if temperature fluctuations within the sensor support layer 112 cause significant expansion and/or contraction that changes the positional relationship between the first sensor component 110(1) and the second sensor component 110(2), it may become impractical to use stereo vision techniques to confidently and accurately calculate 3-D scene information.

As another specific but non-limiting example, the first sensor component 110(1) may be a light projector for emitting a known pattern of invisible structured light and the second sensor component 110(2) may be an image sensor for detecting reflections of the structured light that have bounced off of objects with the real-world environment. Three-dimensional (3D) scene information may be calculated based on how the detected reflections have been distorted from the known pattern. Similar to stereo vision technologies, it can be appreciated that in structured light technologies the accuracy with which 3D scene information represents the actual real-world environment depends on the degree to which positional relationship between sensor components can be nominally maintained.

In order to mitigate (and in some cases completely eliminate) the affect that temperature fluctuations have on the positional relationship between two or more positionally related sensor components, the sensor support layer 112 may be constructed from materials that minimize a CTE of the sensor support layer 112. In implementations where accurately calculating data that is representative of a real-world environment is dependent on maintaining a nominal positional relationship between the sensor components 110, constructing the sensor support layer 112 to have a CTE as close to zero as possible may be desirable. As used herein, the term “positionally related sensor components” generally refers to sensor components that are designed for operation at a nominal positional relationship with respect to one another. Exemplary such positionally related sensor components include, but are not limited to, first and second cameras within a stereo vision system, a projector and a light sensor within a structured light system, and so on.

In some embodiments, the sensor support layer 112 may be a fiber reinforced polymer having a CTE that is low enough for the sensor support layer 112 to be described as substantially thermally nonresponsive. As a specific but non-limiting example, the sensor support layer 112 may be a cured epoxy resin having embedded therein a plurality of carbon fibers that are arranged so as to have axial directions that generally extend between the first sensor component 110(1) and the second sensor component 110(2). In such an embodiment, it is practicable to achieve a CTE between the sensor components 100 that zero or at least approximately zero (e.g., less than 1 PPM, less than 0.5 PPM, etc.).

As used herein, the term “thermally nonresponsive” may be used to refer to a material and/or component of the system 100 which does not change in size and/or shape in response to temperature fluctuations. For example, a layer of the system 100 which has a CTE that is equal to zero (“0”) PPM may aptly be described as a thermally nonresponsive layer. The term “substantially thermally nonresponsive” may be used to refer to a material and/or component of the system 100 having a CTE that is within a threshold level from 0 PPM (e.g., between −5 and 5 PPM, between −4 and 4 PPM, between −3 and 3 PPM, between −2 and 2 PPM, between −1 and 1 PPM).

As illustrated, the sensor support layer 112 has an outer side 114 on which the sensor components 110 are mechanically coupled at the nominal distance relationship from one another. Additionally, or alternatively, the “positionally related” sensor components 110 may be coupled to the outer side 114 of the sensor support layer 112 at a nominal angular orientation with respect to one another. The sensor components 110 may be electrically connected to the conductive tracks 104 of the circuit board layer 102. In this way, the sensor components 110 may be mechanically coupled to the outer side 114 of the sensor support layer 112 to generate data that accurately represents the real-world environment (since the sensor support layer 112 maintains them at the nominal positional relationship due to its “low” CTE) while being concurrently electrically coupled to the circuit board layer 102 to communicate this data to the “interconnected” electronic components 106 that are coupled to the circuit board layer 102 (which expands and contracts as the electronic components 106 cause temperature fluctuations therein).

In the illustrated embodiment, the system 100 further includes an adhesive layer 116 that mechanically couples the sensor support layer 112 to the circuit board layer 102. This enables the sensor components 110 to be mechanically coupled to the circuit board layer 102 without the positional relationship between the sensor components 110 deviating from a nominal positional relationship—even as the circuit board layer 102 expands and contracts due to temperature fluctuations. Thus, the various electronic components 106 which are included within the system 100 (e.g., processor units coupled to the circuit board layer 102) can emit large amounts of heat without causing relative movement to occur between sensor components 110.

In some embodiments, the system 100 may include a vapor chamber 118 for absorbing heat that is emitted from various components of the system 100. For example, as illustrated, the vapor chamber 118 is positioned in thermal contact with the electronic components 106 to quickly draw heat away from these electronic components 106 and to prevent the emitted heat from being absorbed by the circuit board layer 102 and conductively transferred through the adhesive layer 116 and/or the sensor support layer 112. Additionally, or alternatively, a vapor chamber may be positioned in thermal contact with the sensor components 110 to shunt heat that is generated by the sensor components 110 to a region for heat dissipation.

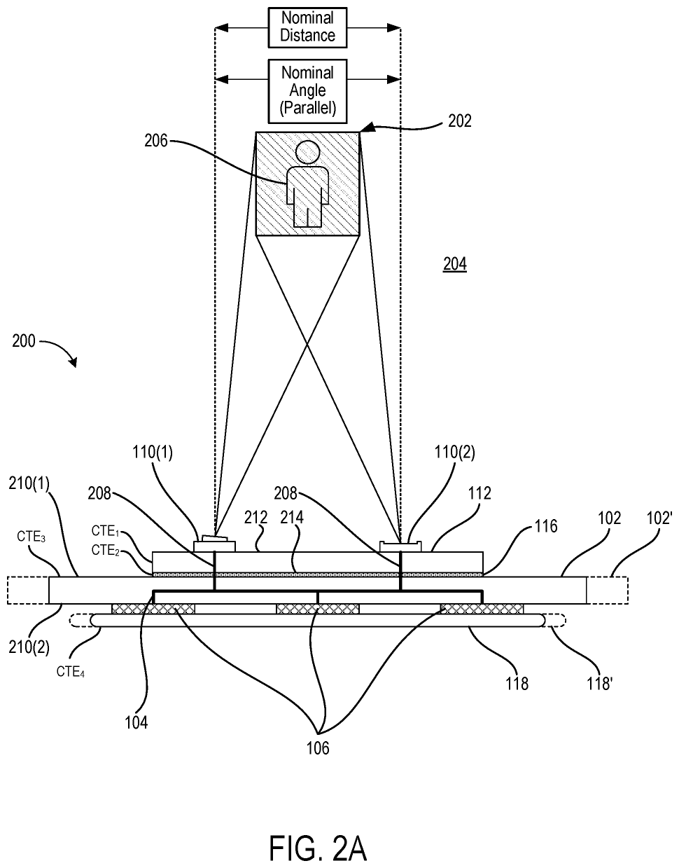

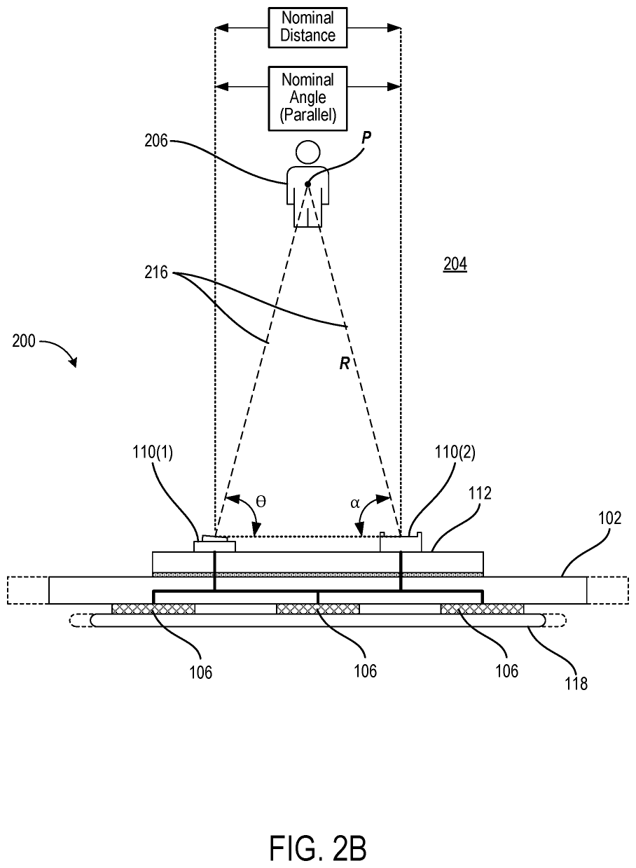

Turning now to FIG. 2A, illustrated is a side view of an exemplary system 200 in which a circuit board layer 102 supporting various electronic components 106 and a sensor support layer 112 supporting two positionally related sensor components 110 are mechanically coupled together via an adhesive layer 116. In the illustrated example, the first sensor component 110(1) is configured to emit a structured pattern 202 of invisible light into a real-world environment 204. Some portion of the structured pattern 202 of invisible light is reflected off of an object 206 within the real-world environment 204 back to the second sensor component 110(2) which is configured to detect the reflected light. The system 200 may calculate 3D scene information based upon how the structured pattern 202 is deformed by the object 206. As described above, the accuracy with which the calculated 3D scene information represents the actual physical characteristics of the object 206 is dependent upon how closely a nominal positional relationship between the first sensor component 110(1) and the second sensor component 110(2) is maintained. Accordingly, the sensor support layer 112 is constructed so as to minimize, and in some embodiments even eliminate, changes in size and/or shape in response to temperature fluctuations.

As shown in FIG. 2A, various layers of the system 200 have different CTE values and, therefore, respond differently to temperature fluctuations that occur during operation. Specifically, the sensor support layer 112 is labeled as having a first CTE (labeled CTE₁), the adhesive layer 116 is labeled as having a second CTE (labeled CTE₂), the circuit board layer 102 is labeled as having a third CTE (labeled CTE₃), and a vapor chamber 118 is labeled as having a fourth CTE (labeled CTE₄). In some embodiments, the first CTE of the sensor support layer 112 may be approximately zero such that the sensor support layer 112 does not change in size and/or shape in response to temperature fluctuations. This results in a positional relationship between the first sensor 110(1) and the second sensor 110(2) being nominally maintained notwithstanding temperature variations that occur within the sensor support layer 112 during operation. For example, the system 200 may begin to perform computationally intensive tasks such as tracking the object 206 and this may cause one or more of the electronic components 106 to emit large amounts of heat. Some of this heat may inevitably reach the sensor support layer 112; however, due to the first CTE being approximately zero a nominal distance between sensor components 110 will be maintained.

In contrast to the sensor support layer 112, the circuit board layer 102 may undergo expansion and/or contraction in response to these temperature fluctuations. For example, the circuit board layer 102 may be constructed from a material that results in the third CTE being X PPM (X being a positive integer value) such that a temperature fluctuation may cause the circuit board layer 102 to expand to the shape shown by the dotted outline labeled 102′. As a specific but nonlimiting example, the circuit board layer 102 to be constructed from a ceramic material having a CTE of 60 PPM such that a temperature fluctuation of 70° C. results in the circuit board layer 102 expanding and/or contraction by 4200 PPM.

In some implementations, the fourth CTE of the vapor chamber 118 is less than the third CTE of the circuit board layer 102. As a specific but nonlimiting example, the vapor chamber 118 may be made from a titanium alloy that results in the fourth CTE being 10 PPM. In this example, a temperature fluctuation of 35° C. results in the titanium alloy vapor chamber 118 expanding and/or contracting by 350 PPM. In FIG. 2A, the dotted outline labeled 118′ is indicative of the expanded state of the vapor chamber 118.

In various implementations, the second CTE of the adhesive layer 116 is greater than the first CTE of the sensor support layer 112 and is less than the third CTE of the circuit board layer 102. Accordingly, the second CTE of the adhesive layer 116 may aptly be described as an intermediate CTE since its value lies between the different CTEs of the layers which it adheres together. In some embodiments, the adhesive layer 116 may include a predetermined ratio of filler materials which cause the adhesive layer 116 to have the intermediate CTE in order to reduce the stresses that result from thermal mismatch between the circuit board layer 102 and the sensor support layer 112. Exemplary filler materials include, but are not limited to, silica and aluminum. In some embodiments, the filler materials are added to an epoxy resin at a predetermined ratio (which may be measured on a per weight and/or per volume basis) to obtain a desired intermediate CTE. As a specific but nonlimiting example, an epoxy resin may be filled with spherical silica filler material to achieve an intermediate CTE of 30 PPM for the adhesive layer 116 which adheres together a sensor support layer 112 having a CTE of approximately zero (“0”) and a circuit board layer 102 having a CTE of approximately sixty (“60”) PPM.

In some implementations, the system 200 includes an electric path that interconnects the sensor components 110 and the electronic components 106 (e.g., to enable data signals to pass therebetween). The electric path may include conductive traces 104 that are integrated into the circuit board layer 102. The electric path may further include one or more wires 208 that extend through one or more of the sensor support layer 112, the adhesive layer 116, and the circuit board layer 102. In the illustrated example, the wires 208 are shown to pass through the sensor support layer 112 and the adhesive layer 116 and to be connected to the conductive traces 104.

In some implementations, the circuit board layer 102 may include conductive traces 104 on both of a first side 210(1) of the circuit board layer 102 and a second side 210(2) of the circuit board layer 102. In the illustrated example, electronic components are mechanically coupled to the second side 210(2) of the circuit board layer 102. For example, the second side 210(2) may include one or more sockets into which the electronic components 106 may be inserted and/or soldered. Also, in the illustrated example, the sensor components 110 are mechanically coupled to an outer side 212 of the sensor support layer 112. The adhesive layer 116 is disposed between an inner side 214 of the sensor support layer 112 and the first side 210(1) of the circuit board layer 102.

FIG. 2B is a side view of the exemplary stack of FIG. 2A showing an exemplary light path 216 that is emitted by a first sensor component 110(1) and is sensed by a second sensor component 110(2). Under circumstances in which a nominal distance and a nominal angle (which may be a parallel angle such as zero degrees) between the first sensor component 110(1) and the second sensor component 110(2) is maintained, the exemplary light path 216 may be usable to calculate a location of a point (labeled P in FIG. 2B) in the real-world environment 204. It can be appreciated that by calculating hundreds or even thousands of points in this way three-dimensional (3D) scene information (e.g., point cloud data) may be compiled that represents the real-world environment 204.

As illustrated, the light path 214 is emitted from the first sensor component 110(1) at a first angle (labeled [symbol] in FIG. 2B) and propagates through the real-world environment 204 until striking the object 206 which reflects some of the light back toward the second sensor component 110(2). The second sensor component 110(2) may sense a second angle (labeled α in FIG. 2B) at which a reflected portion of the emitted light strikes the second sensor 110(2). Assuming the nominal distance and nominal angle are both maintained between the sensor components 110, an exemplary equation for calculating the distance (labeled R in FIG. 2B) to the point P is as follows.

$$R = Nominal Distance \times \frac{sin ( θ )}{sin ( α + θ )} \qquad ( Eq . 1 )$$

It can be appreciated however that the foregoing may yield inaccurate information if either one of the nominal distance or nominal angle are not adequately maintained. Accordingly, various embodiments of the sensor support layer 112 disclosed herein are designed to be thermally nonresponsive and, therefore, to maintain their precise shape notwithstanding temperature fluctuations. It can be appreciated that mounting the sensor components 110 to a thermally non-responsive sensor support layer 112 which is then adhered to a circuit board layer 102 to indirectly mount the sensor components 110 to circuit board layer 102 provides marked benefits over directly mounting the sensor components 110 to the circuit board layer—since this layer will inevitable expand and contract in response to temperature fluctuations and, therefore, is ill suited to adequately maintain the nominal positional relationship as operational conditions fluctuate.

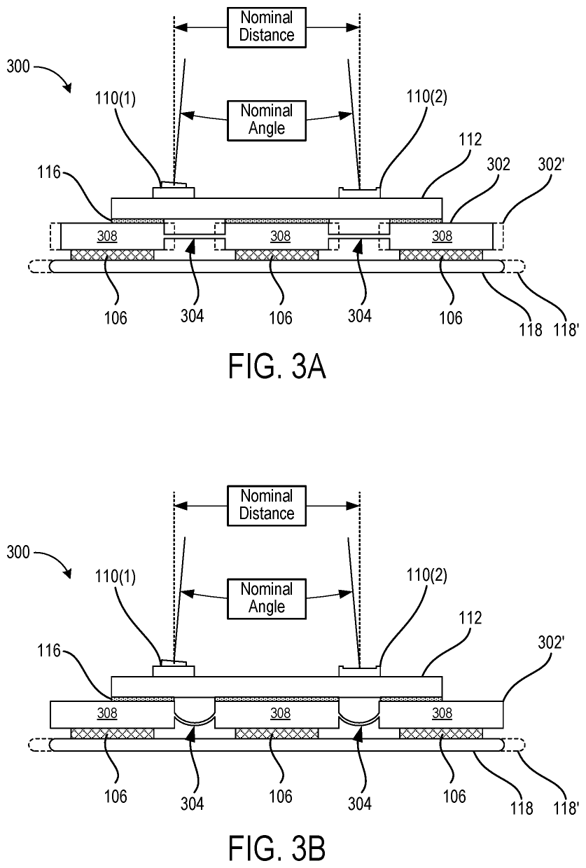

FIGS. 3A and 3B (collectively referred to as FIG. 3) illustrated an alternative embodiment of an electro-thermal system 300 at two different temperatures. With specific reference to FIG. 3A, illustrated is an exemplary system 300 comprising a circuit board 302 that includes one or more flexible regions 304 and one or more substantially rigid regions 308. In some embodiments, electronic components 106 are mounted to the substantially rigid regions 308 of the circuit board 302. In the illustrated example, the flexible regions 304 are positioned between the substantially rigid regions 308 on which the electronic components 106 are mounted. Temperature fluctuations cause the substantially rigid regions 308 of the circuit board 302 to expand to the relatively larger shape that is shown by the dotted outline labeled 302′. The adhesive layer 116 may be disposed between the substantially rigid regions 308 of the circuit board 302 and the sensor support layer 112. The sensor support layer 112 may have a relatively lower CTE than the circuit board 302 to maintain a nominal distance and/or nominal angle between the first sensor component 110(1) and the second sensor component 110(2) notwithstanding temperature fluctuations. For example, the sensor support layer 112 may have a CTE of zero (“0”) PPM and in such instances will not expand or contract. Accordingly, in FIGS. 3A & 3B there is no dotted like outline to represent any sort of range of shape changes with respect to the sensor support layer 112.

FIG. 3B illustrates the system 300 of FIG. 3A at a relatively higher temperature than shown in FIG. 3A such that the circuit board 302′ is in the expanded state that is represented by the dotted line outline 302′ of FIG. 3A. As illustrated, in the expanded state the substantially rigid portions 308 of the circuit board 302 have expanded horizontally both to the left and to the right which has caused the flexible regions 304 to change shape (e.g., by bending into a curve). It can be appreciated that since the substantially rigid portions 308 of the circuit board 302 are enabled to expand in both directions, the amount of stress caused at a boundary between the circuit board layer 102 and the adhesive layer 116 may be relatively less than in other embodiments in which the entire circuit board layer 102 is substantially rigid. This is because the total strain (e.g., relative movement) between the circuit board layer 102 and the adhesive layer 116 and/or the sensor support layer 112 is decreased in the embodiment of FIG. 3 as opposed to the embodiments shown in FIGS. 1 and 2.

In some embodiments, the flexible regions 304 of the circuit board 302 are constructed from a polyimide film having etched thereon a plurality of conductive traces. The conductive traces may be added to the polyimide film using an additive process (e.g., by vacuum depositing copper directly onto the polyimide film) or a subtractive process (e.g., by using an etching process to define the conductive traces). In some embodiments, the flexible regions 304 of the circuit board 302 may be made from a Liquid Crystal Polymer.

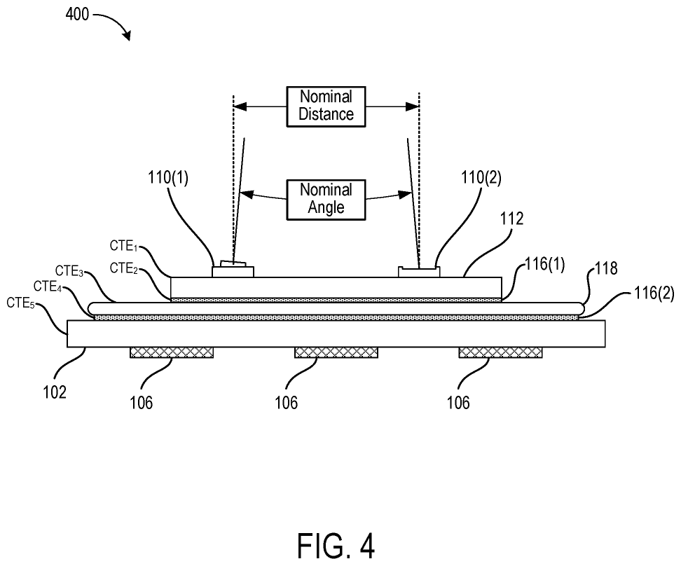

FIG. 4 illustrates an exemplary system 400 that includes a vapor chamber 118 disposed between a circuit board layer 102 supporting one or more electronic components 106 and a sensor support layer 112 supporting one or more sensor components 110. During operation of the system 400 heat that is emitted by the electronic components 106 is prevented from reaching the sensor support layer 112 by virtue of the vapor chamber 118 being disposed therebetween. For example, heat that propagates conductively through the circuit board layer 102 toward the sensor support layer 112 will be absorbed into the vapor chamber 118 and substantially dissipated into an ambient environment rather than passing through to the sensor support layer 112.

As illustrated, the sensor support layer 112 may be adhered to the vapor chamber 118 via a first adhesive layer 116(1) and the vapor chamber 118 may be adhered to the circuit board layer via a second adhesive layer 116(1). In some embodiments, one or both of the adhesive layers 116 may have an intermediate CTE to reduce thermal mismatch between various layers of the system 400. Stated alternatively, the first adhesive layer 116(1) may have a CTE that is less than the vapor chamber 118 but greater than the sensor support layer 112 whereas the second adhesive layer 116(2) may have a CTE that is less than the circuit board layer 102 but greater than the vapor chamber 118. As a specific but nonlimiting example, the sensor support layer 112 may have a first CTE that is less than 10 PPM, the first adhesive layer 116(1) may have a second CTE that is greater than 10 PPM and less than 20 PPM, the vapor chamber 118 may have a third CTE that is greater than 20 PPM and less than 30 PPM, the second adhesive layer 116(2) may have a fourth CTE that is greater than 30 PPM and less than 40 PPM, and the circuit board layer 102 may have a fifth CTE that is greater than 40 PPM.

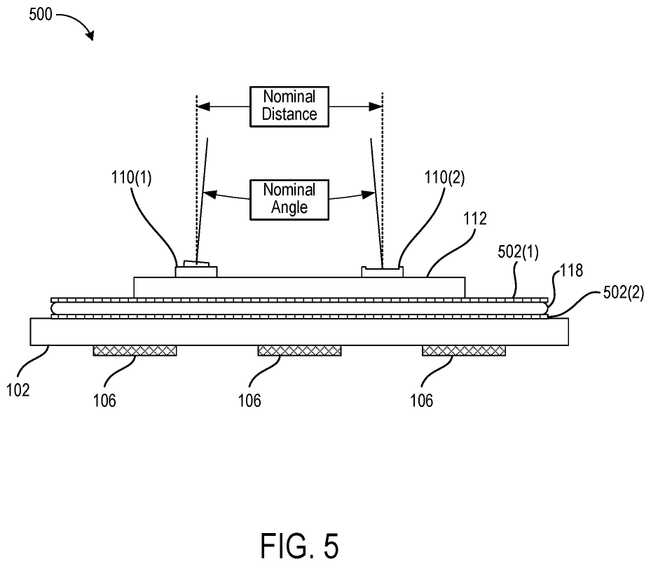

FIG. 5 illustrates an exemplary electro-thermal system 500 that includes a vapor chamber 118 that is disposed between two layers of a material 502 that restricts expansion and contraction of the vapor chamber 118. For example, the material 502 may be an nickel-iron allow having a notably low CTE such as, for example, FeNi36 (64FeNi) colloquially referred to as Invar. In some embodiments, the material 502 may have a relatively lower CTE than the vapor chamber 118. As a specific but non-limiting example, the vapor chamber 118 may be a titanium-based vapor chamber 118 have a CTE of approximately 10 PPM whereas the material may have a CTE of a mere 1.5 PPM. Then, the two layers of the material 502 may be laminated together with the vapor chamber 118 to reduce the overall CTE of the vapor chamber stack (i.e., the combined layers of material 502 sandwiched around the vapor chamber 118). As a specific but non-limiting example, laminating two layers of Invar material having a CTE of 1.5 PPM to a vapor chamber 118 having a CTE of 10 PPM may result in a vapor chamber stack having an overall (e.g., combined/aggregated) CTE of less than 5 PPM—depending on the relative thickness of the vapor chamber 118 and the layers of the material 502.

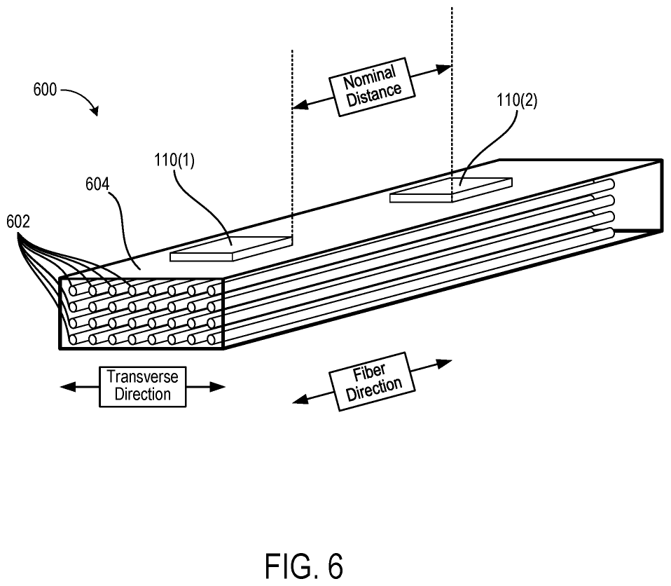

FIG. 6 illustrates an exemplary sensor support layer 600 that includes a plurality of fibers 602 embedded within a polymer 604 and extending between a first sensor component 110(1) and a second sensor component 110(2). As illustrated, in various embodiments, at least some of the fibers 602 may be arranged so that a fiber direction (e.g., an axial/longitudinal direction of the fiber(s)) extends generally between the first sensor component 110(1) and the second sensor component 110(2). It can be appreciated that such embodiments in which a substantial amount of fibers 602 are oriented to longitudinally extend between locations at which the sensor components 110 are mounted may practically result in the sensor support layer 112 having a CTE of zero (“0”) in the fiber direction. Stated alternatively, the sensor support layer 600 may be a thermally nonresponsive in a direction that runs between the “positionally related” sensor components 110.

In some embodiments, the sensor support layer 600 is isotropic in the sense that the CTE of the sensor support layer 600 is directionally independent. For example, the amount that the sensor support layer 600 expands and/or contracts in response to a given temperature fluctuation will be the same in all directions. In some embodiments, the sensor support layer 600 is anisotropic in the sense that the CTE of the sensor support layer 600 is directionally dependent. For example, as illustrated in FIG. 5, various embodiments of the sensor support layer 600 may be include a fiber direction that defines a direction in which the fibers 602 predominantly run and a transverse direction in which relatively fewer fibers run. It can be appreciated that in the illustrated embodiment the sensor support layer 600 may have a different CTEs that correspond to the fiber direction and the transverse direction. As a specific but non-limiting example, the sensor support layer 600 may be thermally nonresponsive along the fiber direction (e.g. have a CTE of approximately zero PPM in the fiber direction) while being thermally responsive along the transverse direction (e.g., have a CTE greater than zero PPM in the transverse direction).

It should be appreciated any reference to “first,” “second,” etc. items and/or abstract concepts within the description is not intended to and should not be construed to necessarily correspond to any reference of “first,” “second,” etc. elements of the claims. In particular, within this Detailed Description and/or the previous Summary, items and/or abstract concepts such as, for example, sides of individual layers and/or CTEs and/or sensor components may be distinguished by numerical designations without such designations corresponding to the claims or even other paragraphs of the Summary and/or Detailed Description. For example, any designation of a “first CTE” and “second CTE” within a paragraph of this disclosure is used solely to distinguish two different CTEs within that specific paragraph—not any other paragraph and particularly not the claims.

FIGS. 1-6 illustrate various alternate embodiments of the system(s) disclosed herein. Specific details being illustrated in the FIGS (and/or described in the Summary or Detailed Description) with another specific detail or, alternatively, apart from another specific detail is not intended to be construed as a limitation. Thus, any individual detail illustrated in and/or described with respect to any figure herein may be combined in any practicable manner with any other individual detail illustrated in and/or described with respect to any other figure herein.

The presently disclosed techniques are believed to be applicable to a variety of systems and approaches involving mounting components to a low CTE layer of a multilayer electro-thermal system. Aspects of this disclosure are predominantly disclosed in the context of mounting positionally related sensor components to a sensor support layer that is made of a carbon fiber reinforced polymer. Aspects of this disclosure are also predominantly disclosed in the context of the sensor support layer being mechanically coupled to a circuit board layer via an adhesive having an intermediate CTE (e.g., a CTE that is less than a first CTE of the circuit board layer and greater than a second CTE of the sensor support layer). While the presently disclosed techniques are not necessarily limited to these specific implementation details, an appreciation of various aspects of the disclosed techniques is best gained through a discussion of examples in the aforementioned contexts. However, the structural support layer may be constructed from a variety of structural base materials, can have a CTE that is less than or greater than other layers of the multiple layers, and can be coupled to one or more other layers in a variety of different ways (e.g., adhesives, mechanical fasteners, soldering, etc.) These and other variations shall be considered variations that do not depart from the present disclosure.

### Example Clauses

The disclosure presented herein may be considered in view of the following clauses.

Example Clause A, a multi-layer interconnected electro-thermal system, comprising: a circuit board layer having a first side and a second side, wherein the circuit board layer has a first coefficient of thermal expansion (CTE); a sensor support layer having an inner side and an outer side, wherein the sensor support layer has a second CTE that is less than the first CTE of the circuit board layer; a plurality of sensor components that are electrically coupled to the circuit board layer, to provide environmental data to a processor, and mechanically coupled to the outer side of the sensor support layer to nominally maintain at least one positional relationship between individual sensor components of the plurality of sensor components; an adhesive layer between the first side of the circuit board layer and the inner side of the sensor support layer to mechanically couple the sensor support layer to the circuit board layer; and a heat source that is mechanically coupled to the second side of the circuit board layer.

Example Clause B, the multi-layer interconnected electro-thermal system of Example Clause A, further comprising a vapor chamber having a third CTE that is greater than the second CTE and less than the first CTE, wherein the vapor chamber is mounted in thermal contact with the heat source at the second side of the circuit board layer.

Example Clause C, the multi-layer interconnected electro-thermal system of any one of Example Clauses A through B, wherein the adhesive layer includes a predetermined ratio of at least one filler material that causes the adhesive layer to have an intermediate CTE that is less than the first CTE and greater than the second CTE.

Example Clause D, the multi-layer interconnected electro-thermal system of any one of Example Clauses A through C, wherein the sensor support layer that has the second CTE is a fiber-reinforced polymer.

Example Clause E, the multi-layer interconnected electro-thermal system of Example Clause D, wherein the fiber-reinforced polymer includes a plurality of carbon fibers.

Example Clause F, the multi-layer interconnected electro-thermal system of any one of Example Clauses A through E, wherein the heat source that is mechanically coupled to the second side of the circuit board layer is the processor that the environmental data is provided to by the plurality of sensor components.

Example Clause G, the multi-layer interconnected electro-thermal system of any one of Example Clauses A through F, wherein the circuit board layer includes one or more rigid regions and one or more flexible regions, and wherein the heat source is the processor that is mounted to an individual rigid region of the one or more rigid regions.

Example Clause H, the multi-layer interconnected electro-thermal system of any one of Example Clauses A through G, wherein the plurality of sensor components includes a first sensor component for emitting light and a second sensor component for detecting reflections of the light at a predetermined nominal distance from the first sensor component.

Example Clause I, the multi-layer interconnected electro-thermal system of any one of Example Clauses A through H, further comprising at least one wire that extends from at least one sensor component of the plurality of sensor components through the sensor support layer to at least one conductive trace at the circuit board layer.

Example Clause J, an apparatus comprising: a circuit board layer having a first coefficient of thermal expansion (CTE); a sensor support layer having a second CTE that is less than the first CTE of the circuit board layer; a first sensor component that is mechanically coupled to the sensor support layer; a second sensor component that is positionally related to the first sensor component and this is mechanically coupled to the sensor support layer at a nominal positional relationship from the first sensor component, wherein the nominal positional relationship includes at least a nominal distance and a nominal angle; and an adhesive layer having an intermediate CTE that is less than the first CTE and greater than the second CTE, wherein the adhesive layer is between the circuit board layer and the sensor support layer to indirectly couple the first sensor component and the second sensor component to the circuit board layer in accordance with the nominal positional relationship.

Example Clause K, the apparatus of Example Clause J, further comprising a vapor chamber that is disposed adjacent to one or more electronic components that are mounted to the circuit board layer, wherein the vapor chamber has a third CTE that is greater than the second CTE and less than the first CTE.

Example Clause L, the apparatus of any one of Example Clauses J through K, wherein the sensor support layer is a carbon fiber reinforced polymer that is thermally nonresponsive in order to lock the relative position between the first sensor component and the second sensor component.

Example Clause M, the apparatus of any one of Example Clauses J through L, wherein the carbon fiber reinforced polymer is isotropic.

Example Clause N, the apparatus of any one of Example Clauses J through M, wherein the circuit board layer includes at least two rigid regions and a flexible region that is disposed between the at least two rigid regions, and wherein the adhesive layer is between the at least two substantially rigid regions and the sensor support layer.

Example Clause O, the apparatus of any one of Example Clauses J through N, wherein the adhesive layer is an epoxy that includes filler material that causes the adhesive layer to have the intermediate CTE.

Example Clause P, a system, comprising: a first sensor component and a second sensor component that is positionally related to the first sensor component; a sensor support layer for supporting the first sensor component and the second sensor component; a vapor chamber having a first side and a second side that is mechanically coupled to the sensor support layer; a circuit board layer that is mechanically coupled to the first side of the vapor chamber; and at least one electronic component that is electrically coupled to one or more conductive traces of the circuit board layer.

Example Clause Q, the system of Example Clause P, wherein the sensor support layer is mechanically coupled to the vapor chamber via a first adhesive layer that has a first intermediate CTE, and wherein the vapor chamber is mechanically coupled to the circuit board layer via a second adhesive layer that has a second intermediate CTE.

Example Clause R, the system of any one of Example Clauses P through Q, wherein at least one of the first sensor component or the second sensor component are electrically coupled to the at least one electronic component.

Example Clause S, the system of any one of Example Clauses P through R, further comprising a nickel-iron alloy layer having a first CTE that is relatively lower than a second CTE of the vapor chamber, wherein the nickel-iron alloy layer is disposed between the vapor chamber and the sensor support layer.

Example Clause T, the system of any one of Example Clauses P through S, wherein the sensor support layer is at least one a carbon fiber reinforced polymer.

### CONCLUSION

In closing, although the various techniques have been described in language specific to structural features and/or methodological acts, it is to be understood that the subject matter defined in the appended representations is not necessarily limited to the specific features or acts described. Rather, the specific features and acts are disclosed as example forms of implementing the claimed subject matter.

What is claimed is:

1. A multi-layer interconnected electro-thermal system, comprising:
a circuit board layer having a first side and a second side, wherein the circuit board layer has a first coefficient of thermal expansion (CTE);
a sensor support layer having an inner side and an outer side, wherein the sensor support layer has a second CTE that is less than the first CTE of the circuit board layer;
a plurality of sensor components that are electrically coupled to the circuit board layer, to provide environmental data to a processor, and mechanically coupled to the outer side of the sensor support layer to nominally maintain at least one positional relationship between individual sensor components of the plurality of sensor components;
an adhesive layer between the first side of the circuit board layer and the inner side of the sensor support layer to mechanically couple the sensor support layer to the circuit board layer; and
a heat source that is mechanically coupled to the second side of the circuit board layer.

2. The multi-layer interconnected electro-thermal system of claim 1, further comprising a vapor chamber having a third CTE that is greater than the second CTE and less than the first CTE, wherein the vapor chamber is mounted in thermal contact with the heat source at the second side of the circuit board layer.

3. The multi-layer interconnected electro-thermal system of claim 1, wherein the adhesive layer includes a predetermined ratio of at least one filler material that causes the adhesive layer to have an intermediate CTE that is less than the first CTE and greater than the second CTE.

4. The multi-layer interconnected electro-thermal system of claim 1, wherein the sensor support layer that has the second CTE is a fiber-reinforced polymer.

5. The multi-layer interconnected electro-thermal system of claim 4, wherein the fiber-reinforced polymer includes a plurality of carbon fibers.

6. The multi-layer interconnected electro-thermal system of claim 1, wherein the heat source that is mechanically coupled to the second side of the circuit board layer is the processor that the environmental data is provided to by the plurality of sensor components.

7. The multi-layer interconnected electro-thermal system of claim 1, wherein the circuit board layer includes one or more rigid regions and one or more flexible regions, and wherein the heat source is the processor that is mounted to an individual rigid region of the one or more rigid regions.

8. The multi-layer interconnected electro-thermal system of claim 1, wherein the plurality of sensor components includes a first sensor component for emitting light and a second sensor component for detecting reflections of the light at a predetermined nominal distance from the first sensor component.

9. The multi-layer interconnected electro-thermal system of claim 1, further comprising at least one wire that extends from at least one sensor component of the plurality of sensor components through the sensor support layer to at least one conductive trace at the circuit board layer.

10. An apparatus comprising:
a circuit board layer having a first coefficient of thermal expansion (CTE);
a sensor support layer having a second CTE that is less than the first CTE of the circuit board layer;
a first sensor component that is mechanically coupled to the sensor support layer;
a second sensor component that is positionally related to the first sensor component and this is mechanically coupled to the sensor support layer at a nominal positional relationship from the first sensor component, wherein the nominal positional relationship includes at least a nominal distance and a nominal angle; and
an adhesive layer having an intermediate CTE that is less than the first CTE and greater than the second CTE, wherein the adhesive layer is between the circuit board layer and the sensor support layer to indirectly couple the first sensor component and the second sensor component to the circuit board layer in accordance with the nominal positional relationship.

11. The apparatus of claim 10, further comprising a vapor chamber that is disposed adjacent to one or more electronic components that are mounted to the circuit board layer, wherein the vapor chamber has a third CTE that is greater than the second CTE and less than the first CTE.

12. The apparatus of claim 10, wherein the sensor support layer is a carbon fiber reinforced polymer that is thermally nonresponsive in order to lock the relative position between the first sensor component and the second sensor component.

13. The apparatus of claim 10, wherein the carbon fiber reinforced polymer is isotropic.

14. The apparatus of claim 10, wherein the circuit board layer includes at least two rigid regions and a flexible region that is disposed between the at least two rigid regions, and wherein the adhesive layer is between the at least two substantially rigid regions and the sensor support layer.

15. The apparatus of claim 10, wherein the adhesive layer is an epoxy that includes filler material that causes the adhesive layer to have the intermediate CTE.

16. A system, comprising:
a first sensor component and a second sensor component that is positionally related to the first sensor component;
a sensor support layer for supporting the first sensor component and the second sensor component;
a vapor chamber having a first side and a second side that is mechanically coupled to the sensor support layer;
a circuit board layer that is mechanically coupled to the first side of the vapor chamber; and
at least one electronic component that is electrically coupled to one or more conductive traces of the circuit board layer.

17. The system of claim 16, wherein the sensor support layer is mechanically coupled to the vapor chamber via a first adhesive layer that has a first intermediate CTE, and wherein the vapor chamber is mechanically coupled to the circuit board layer via a second adhesive layer that has a second intermediate CTE.

18. The system of claim 16, wherein at least one of the first sensor component or the second sensor component are electrically coupled to the at least one electronic component.

19. The system of claim 16, further comprising a nickel-iron alloy layer having a first CTE that is relatively lower than a second CTE of the vapor chamber, wherein the nickel-iron alloy layer is disposed between the vapor chamber and the sensor support layer.

20. The system of claim 16, wherein the sensor support layer is at least one a carbon fiber reinforced polymer.
